(19) United States
(12) Patent Application Publication
(10) Pub. No.: US 2014/0347054 A1
(43) Pub. Date: Nov. 27, 2014

(54) Magnetic Resonance System with Whole-Body Transmitting Array

(71) Applicants: Ralph Kimmlingen, Zirndorf (DE); Norbert Rietsch, Dormitz (DE)

(72) Inventors: Ralph Kimmlingen, Zirndorf (DE); Norbert Rietsch, Dormitz (DE)

(21) Appl. No.: 14/283,764

(22) Filed: May 21, 2014

(30) Foreign Application Priority Data
May 23, 2013 (DE) DE 102013209609.7

(51) Int. Cl. G01R 33/38

(52) U.S. Cl. CPC G01R 33/38
USPC 324/322

(57) ABSTRACT

A magnetic resonance system includes a basic magnet that surrounds a cylindrical examination volume of the magnetic resonance system, the cylindrical examination volume defining a longitudinal axis, and a send structure configured to generate a high frequency excitation field (B1) in the examination volume. The high frequency excitation field is configured to excite an object to be examined in the examination volume, such that the object emits magnetic resonance signals. The basic magnet is configured to generate a basic magnetic field (B0) in the examination volume that is constant over time and at least substantially homogeneous spatially. The send structure includes at least first transmitting antennae and second transmitting antennae that are configured to load the examination volume with the high frequency excitation field (B1).

### RELATED APPLICATIONS

This application claims the benefit of German Patent Application No. DE 102013209609.7, filed May 23, 2013, the entire contents of which are hereby incorporated herein by reference.

### TECHNICAL FIELD

The present teachings relate generally to magnetic resonance systems.

### BACKGROUND

A magnetic resonance system has a basic magnet that radially surrounds a cylindrical examination volume of a magnetic resonance system. The cylindrical examination volume defines a longitudinal axis. The basic magnet generates a basic magnetic field in the examination volume. The basic magnetic field is constant over time and at least substantially homogeneous spatially. The magnetic resonance system has a send structure (e.g., a transmission structure) that may generate a high frequency excitation field in the examination volume. The high frequency excitation field may excite an object to be examined in the examination volume, such that the object emits magnetic resonance signals. The send structure includes at least first transmitting antennae and second transmitting antennae to load the examination volume with the high frequency excitation field.

Conventionally, at low basic magnetic field strengths (e.g., a magnetic field strength of 1.5 Tesla), whole-body transmitting antennae are used to uniformly or almost uniformly cover the entire examination volume with a high frequency excitation field. An example of a conventional whole-body transmitting antenna is a birdcage resonator. The use of such a conventional antenna is unproblematic when the field strength of the basic magnetic field of is, for example, 1.5 Tesla. However, at higher field strengths of the basic magnetic field (e.g., a magnetic field strength of 7 Tesla), the transmitting resonators may have low efficiency due to the short wavelength of the excitation field (e.g., proton imaging). The power requirement increases quadratically with the field strength and the Larmor frequency. Furthermore, the range of the transmitting antennae is reduced as the Larmor frequency increases. Thus, at greater basic magnetic field strengths, it is difficult to generate a homogeneous field distribution of the high-frequency excitation field. Furthermore, the construction of the basic magnet is complex and cost-intensive. The complexity and cost increase together with the strength of the basic magnetic field to be generated. For this reason, the internal diameter of the basic magnet is 900 mm or less. The gradient coils inter alia are arranged inside this internal diameter. As a result, the spatial conditions in the examination volume (e.g., examination tunnel) are constricted. There maybe insufficient space available for a potential whole-body transmitting antenna.

Transmitting antennae may be positioned directly on an object to be examined (e.g., a person). However, transmitting antennae of this type may cover only a portion of the examination volume. Therefore, a plurality of transmitting antennae is used for whole-body coverage.

The resulting field strengths of the excitation field during simultaneous operation of a plurality of transmitting antennae may be determined. However, this determination presupposes knowledge of the arrangement and form of the transmitting antennae. Moreover, the positioning of the transmitting antennae is undefined for transmitting antennae that are arranged directly on the object to be examined. Due to the undefined positioning of the transmitting antennae, determining the interaction of the individual transmitting antennae in advance is difficult to near impossible. Such a determination is may be used to rule out potentially dangerous local increases in the high frequency excitation field. The problems become more manifest if the transmitting antennae are flexible. The form and the arrangement of the transmitting antennae are variable. Thus, in conventional approaches, the coordinated, simultaneous operation of a plurality of such transmitting antennae is difficult or impossible.

For higher basic magnetic field strengths (e.g., a magnetic field strength of 7 Tesla), conventional transmitting antennae are used that bring about only partial coverage of the examination volume. Thus, in research institutes, specific transmitting/receiving coils are used for detecting the heart, for example. Whole-body coverage for magnetic resonance systems with higher field strengths of the basic magnetic field is unknown.

### SUMMARY AND DESCRIPTION

The scope of the present invention is defined solely by the appended claims, and is not affected to any degree by the statements within this summary.

The present embodiments may obviate one or more of the drawbacks or limitations in the related art. For example, in some embodiments, complete (or at least large volume) and substantially homogeneous coverage of the examination volume may be achieved with a high frequency excitation field.

In accordance with the present teachings, a magnetic resonance system of a type described above is provided wherein the first transmitting antennae are arranged in an examination table beneath a top surface thereof. The examination table is configured for conveyance through the examination volume. In addition, the second transmitting antennae are inherently stable and are detachably secured to the examination table and/or to a tunnel wall that radially surrounds the examination volume. During loading of the examination volume with the high frequency excitation field, the second transmitting antennae are arranged in a defined position and orientation above the object to be examined.

The arrangement and form of the first transmitting antennae relative to the examination table may be fixed and therefore known due to the arrangement of the first transmitting antennae beneath the top surface of the examination table. Since the examination table may be moved through the examination tunnel with position control, the arrangement of the first transmitting antennae with respect to the magnetic resonance system as a whole may be determined in an automated manner. Due to the inherent stability of the second transmitting antennae, the form of the second transmitting antennae is also fixed and may therefore be known. Due to securing in a defined position and orientation, the arrangement of the second transmitting antennae with respect to the examination table and/or the magnetic resonance system as a whole may also be known. Despite the use of a plurality of transmitting antennae, the resulting field strengths of the excitation with simultaneous operation of the plurality of transmitting antennae may be determined with a magnetic resonance system in accordance with the present teachings.

The positions of the second transmitting antennae, as viewed in the vertical direction, may be adjusted independently of each other. The second transmitting antennae may be individually positioned from above as close as possible on the object to be examined, thereby maximizing the fill factor and, therefore, the effective coverage.

The first transmitting antennae may be connected to a cooling circuit for a liquid cooling medium. The first transmitting antennae are cooled by the liquid cooling medium. As a result, the first transmitting antennae may be operated with a higher transmitting power.

In some embodiments, the send structure also includes third transmitting antennae configured to load the examination volume with the high frequency excitation field. In some embodiments, the third transmitting antennae, like the second transmitting antennae, are inherently stable and are detachably secured to the examination table and/or the tunnel wall. During loading of the examination volume with the high frequency excitation field, the third transmitting antennae are arranged in a defined position and orientation to a side of the object to be examined. As a result, the coverage of the object to be examined may be further optimized.

The entire examination volume may be loaded with the excitation field by the send structure. Alternatively, only a portion of the examination volume may be loaded with the excitation field by the send structure. In some embodiments, the portion of the examination volume may be arranged to the side relative to the cross-section of the examination volume.

Local coils may be arranged radially inside of the send structure. Magnetic resonance signals emitted by the object to be examined may be received by the coils. The signal-to-noise ratio (SNR) may be optimized as a result.

A magnetic resonance system in accordance with the present teachings may demonstrate its full strengths if the basic magnetic field is strong (e.g., has a strength of at least 3.0 Tesla).

### BRIEF DESCRIPTION OF THE DRAWINGS

FIG. 1 shows a schematic side view of an example of a magnetic resonance system.

FIG. 2 shows a schematic front view of the exemplary magnetic resonance system of FIG. 1.

FIG. 3 shows a schematic side view of an examination table of the exemplary magnetic resonance system of FIG. 1.

FIG. 4 shows an additional schematic front view of the exemplary magnetic resonance system of FIG. 1.

FIG. 5 shows a schematic front view of the exemplary magnetic resonance system of FIG. 1 with a modified send structure.

### DETAILED DESCRIPTION

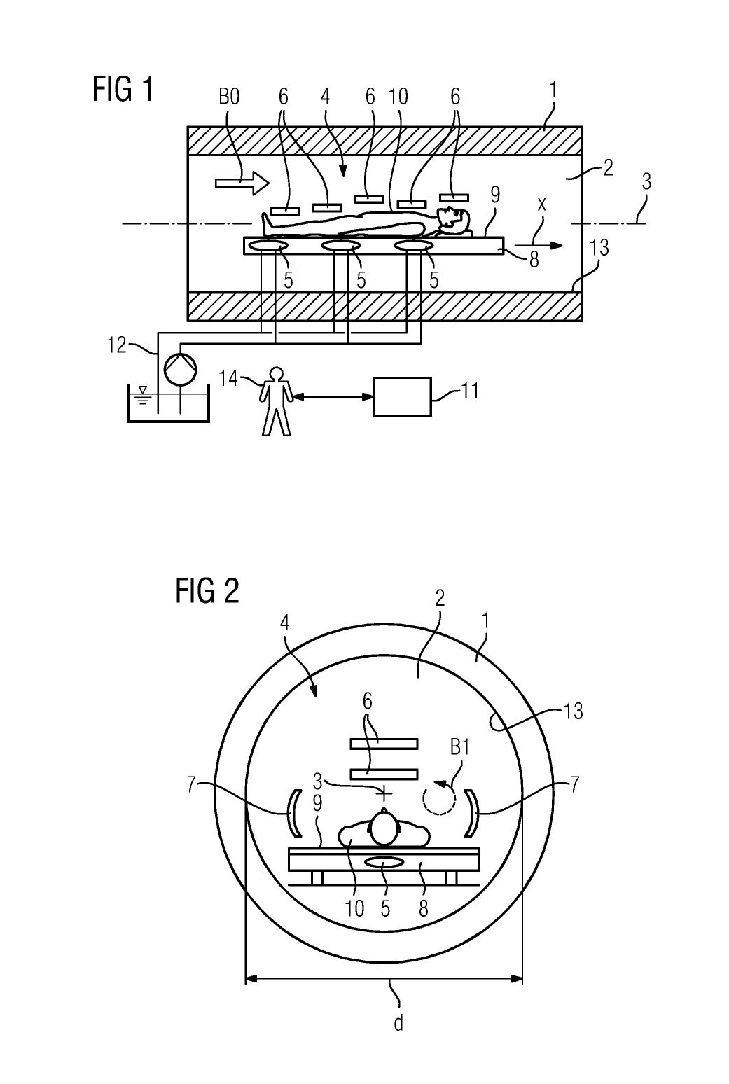

As shown in FIGS. 1 and 2, a magnetic resonance system has a basic magnet 1. The basic magnet 1 radially surrounds a cylindrical examination volume 2 of the magnetic resonance system. The examination volume 2 defines a longitudinal axis 3. The basic magnet 1 generates a basic magnetic field B0 in the examination volume 2. The basic magnetic field B0 is constant over time and is spatially homogeneous or at least substantially homogeneous inside the examination volume 2. By way of example, the basic magnetic field B0 has a strength of at least 3.0 Tesla and, in some embodiments, 7.0 Tesla. The magnetic resonance system also has a gradient system (not shown).

The magnetic resonance system also has a send structure 4. The send structure 4 includes at least first transmitting antennae 5 and second transmitting antennae 6. In some embodiments, the send structure 4 also includes third transmitting antennae 7. There may be a plurality of first transmitting antennae 5 and a plurality of second transmitting antennae 6. The number of third transmitting antennae 7 (if present) may be determined as needed. Each of the first transmitting antenna 5, the second transmitting antenna 6, and the third transmitting antenna 7 may include a plurality of independent elements that may be independently controlled (e.g., array antennae).

The first transmitting antennae 5 are arranged in an examination table 8 and, in some embodiments, beneath a top surface 9 of the examination table 8. The examination table 8 is configured for bearing an object 10 to be examined (e.g., a person). The examination table 8, including the object 10 located thereon that is to be examined, may be conveyed through the examination volume 2 in a conveying direction x. A position-controlled drive (not shown) may be provided for this purpose. Alternatively, the position of the examination table 8 in the conveying direction x may be automatically detected and transmitted to a controller 11 of the magnetic resonance system. Since the first transmitting antennae 5 are arranged beneath the top surface 9, the first transmitting antennae 5 are secured in the examination table 8 in such a way that the first transmitting antennae 5 have a defined form and are fixed relative to the examination table 8. The first transmitting antennae 5 may be connected to a cooling circuit 12 for a liquid cooling medium (e.g., water), as shown in FIGS. 1 and 2. In some embodiments, the first transmitting antennae 5 may be efficiently cooled by the liquid cooling medium and, consequently, be operated with higher performance.

The second transmitting antennae 6 are inherently stable. The second transmitting antennae 6 have a fixed, pre-determined form and may be secured to the examination table 8. Alternatively, the second transmitting antennae 6 may be secured to a tunnel wall 13. The tunnel wall 13 radially surrounds the examination volume 2. The tunnel wall 13 is arranged between the basic magnet 1 and the gradient system on the one hand and the examination volume 2 on the other hand. An arrangement on the tunnel wall 13 may be expedient if the examination volume 2 has a relatively small diameter d. In addition, one part of the second transmitting antennae 6 may be secured to the examination table 8 and a further part of the second transmitting antennae 6 may be secured to the tunnel wall 13. However, the second transmitting antennae 6 are detachably secured regardless of the securing location. The second transmitting antennae 6 may be removed and replaced by other second transmitting antennae 6 that are likewise inherently stable. The second transmitting antennae 6 may be adjusted to the object 10 to be examined and its form (e.g., size).

As shown in FIGS. 1 and 2, the second transmitting antennae 6 are arranged above the object 10 to be examined in a defined position and orientation. The positions of the second transmitting antennae 6, as viewed in the vertical direction, may be adjusted independently of each other. As a result, the fill factor may be optimized. The positions may be defined in this case as well. By way of example, the positions may be automatically detected and supplied to the controller 11. Securing may be done only in specific vertical positions (e.g., in the form of a detent).

The description of the second transmitting antennae 6 provided above is likewise applicable to the third transmitting antennae 7 (if third transmitting antennae 7 are present). The only difference is that the third transmitting antennae 7 are arranged to the side of the object 10 to be examined rather than above the object 10.

A high frequency excitation field B1 is generated in the examination volume 2 by the send structure 4. For this purpose, the examination volume 2 is loaded with the high frequency excitation field B1 by the first transmitting antennae 5 and the second transmitting antennae 6. In some embodiments, third transmitting antennae 7 are optionally also used to load the examination volume 2 with the high frequency excitation field B1. The first transmitting antennae 5, the second transmitting antennae 6, and the optional third transmitting antennae 7 are activated by the controller 11. A plurality of the first transmitting antennae 5, the second transmitting antennae 6, and the third transmitting antennae 7 (and, in some embodiments, all of the first transmitting antennae 5, the second transmitting antennae 6, and the third transmitting antennae 7) are activated simultaneously by the controller 11 at a specific time. The intention is for the high frequency excitation field B1 to excite the object 10 to be examined to emit magnetic resonance signals. The frequency of the excitation field B1 matches the Larmor frequency of the atomic nuclei to be excited (e.g., protons). Other atomic nuclei (e.g., F-17 or P-31) may also be excited.

As described above, the first transmitting antennae 5 are arranged in the examination table 8 beneath the top surface 9. The position of the first transmitting antennae 5 relative to each other is independent of the positioning of the examination table 8 in the conveying direction x. The second transmitting antennae 6 are secured to the examination table 8. The position of the second transmitting antennae 6 relative to each other and relative to the first transmitting antennae 5 is also independent of the positioning of the examination table 8 in the conveying direction x. With respect to the second transmitting antennae 6 that are secured to the tunnel wall 13, the position of the second transmitting antennae 6 relative to each other is independent of the positioning of the examination table 8 in the conveying direction x. However, the position of the second transmitting antennae 6 relative to the first transmitting antennae 5 and relative to the second transmitting antennae 6 secured to the examination table 8 is dependent on the positioning of the examination table 8 in the conveying direction x. Since the positioning of the examination table 8 in the conveying direction x is known to the controller 11, the controller 11 may, in each case, also determine the position of the second transmitting antennae 6 secured to the tunnel wall 13 relative to the first transmitting antennae 5 and relative to the second transmitting antennae 6 secured to the examination table 8. The description provided above in reference to the second transmitting antennae 6 is also applicable to the third transmitting antennae 7.

Since the form and position relative to each other of the first transmitting antennae 5, the second transmitting antennae 6, and the optional third transmitting antennae 7 (if present) are known to the controller 11 at all times, the controller 11 may always determine the resulting excitation field B1 that occurs. The controller 11 may determine the resulting excitation field B1 regardless of which of the first transmitting antennae 5, the second transmitting antennae 6, and the third transmitting antennae 7 are activated, and regardless of the phase and amplitude relationships of the transmitting signals that load the first transmitting antennae 5, the second transmitting antennae 6, and the third transmitting antennae 7. The controller 11 knows the phase and amplitude relationships. Therefore, the transmitting signals may be determined such that the entire examination volume 2 is uniformly (or at least almost uniformly) loaded (e.g., “covered”) with the excitation field B1 by the send structure 4.

By way of example, for shoulder examinations, the second transmitting antennae 6 may be used as shown in FIG. 5 to cover the object 10 that is to be examined on only one side. In this embodiment, only part of the examination volume 2 may be loaded with the excitation field B1 by the send structure 4. As shown in FIG. 5, the loadable part of the examination volume 2 is arranged to the side relative to a cross-section of the examination volume 2 (e.g., as viewed orthogonally to the longitudinal axis 3).

As described above, the second transmitting antennae 6 and the optionally present third transmitting antennae 7 may be removed from the examination table 8 or tunnel wall 13 and replaced by other second transmitting antennae 6 and third transmitting antennae 7. Positioning in different vertical positions may also be achieved. The controller 11 knows at all times which of the second transmitting antennae 6 and, optionally, the third transmitting antennae 7 are being used and how the second transmitting antennae 6 and the third transmitting antennae 7 are positioned. The user 14 of the magnetic resonance system may manually specify corresponding information to the controller 11. The identification of the second transmitting antennae 6 and, optionally, the third transmitting antennae 7 that are used may be automatic. By way of example, the identification may involve appropriately encoded plug connectors. Plug connectors of this kind have been used, for example, for local coils of magnetic resonance systems that are used for receiving purposes. An identification may also be transmitted from the respective second transmitting antenna 6 or third transmitting antenna 7 to the controller 11. The positioning of the second transmitting antennae 6 and, optionally, the third transmitting antennae 7 may be automatically detected as described above. The position (e.g., the vertical position) may even be adjusted automatically. Such methods may also be used, for example, for local coils of magnetic resonance systems that are used for receiving purposes.

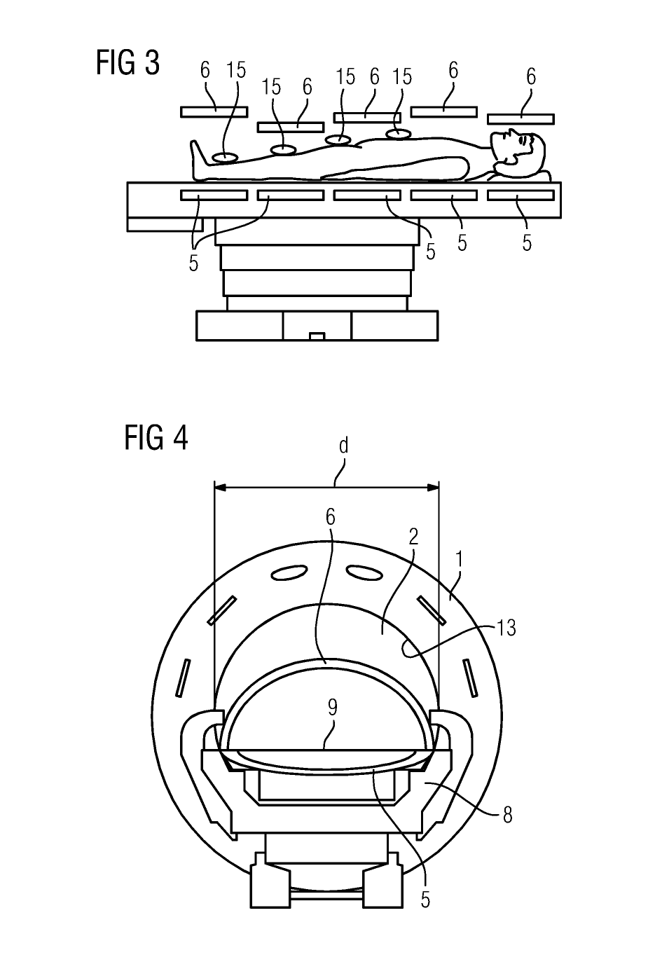

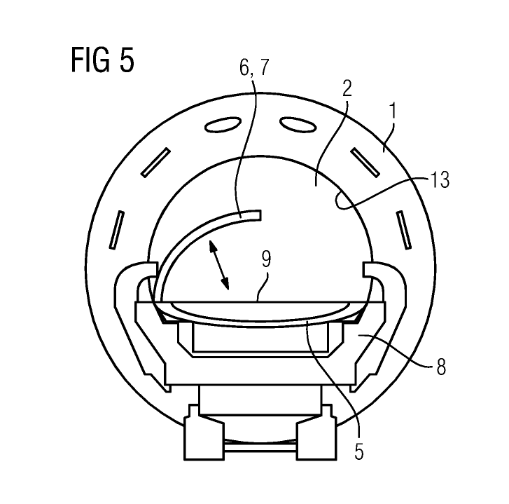

In operating a magnetic resonance system in accordance with the present teachings, the send structure 4 may be used to excite magnetic resonance signals (e.g., to emit the excitation field B1) and to receive excited magnetic resonance signals. As shown in FIG. 3, local coils 15 may be arranged radially inside of the send structure 4. Magnetic resonance signals emitted by the object 10 to be examined may be received by the local coils 15. The send structure 4 may be used solely to emit the excitation field B1 and not to also receive excited magnetic resonance signals.

The present teaching may provide various advantages. For example, despite a high basic magnetic field B0 with a relatively low output, large volume coverage (e.g., in some embodiments, substantially complete coverage) of the examination volume 2 with the excitation field B1 may be achieved. In addition, by operating only individual, or a few of, the first transmitting antennae 5, the second transmitting antennae 6, and the third transmitting antennae 7, specific regions of the examination volume 2 may be purposefully covered by the excitation field B1. A higher SNR may be attained by using the local coils 15 Improved coverage of the trunk of the object 10 to be examined may include the edge regions of the body, (e.g., kidneys, hips, or shoulder).

While the present invention has been described above by reference to various embodiments, it should be understood that many changes and modifications may be made to the described embodiments. It is therefore intended that the foregoing description be regarded as illustrative rather than limiting, and that it be understood that all equivalents and/or combinations of embodiments are intended to be included in this description.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding claim—whether independent or dependent—and that such new combinations are to be understood as forming a part of the present specification.

1. A magnetic resonance system, comprising:
a basic magnet that radially surrounds a cylindrical examination volume of the magnetic resonance system, the cylindrical examination volume defining a longitudinal axis; and
a send structure configured to generate a high frequency excitation field (B1) in the examination volume, the high frequency excitation field being configured to excite an object to be examined in the examination volume, such that the object emits magnetic resonance signals;
wherein the basic magnet is configured to generate a basic magnetic field (B0) in the examination volume, the basic magnetic field being constant over time and at least substantially homogeneous spatially;
wherein the send structure comprises at least first transmitting antennae and second transmitting antennae, the first transmitting antennae and the second transmitting antennae being configured to load the examination volume with the high frequency excitation field (B1);
wherein the first transmitting antennae are arranged in an examination table beneath a top surface thereof, the examination table being configured for conveyance through the examination volume;
wherein the second transmitting antennae are inherently stable and are detachably secured to the examination table, to a tunnel wall that radially surrounds the examination volume, or to the examination table and to the tunnel wall; and
wherein during loading of the examination volume with the high frequency excitation field (B1), the second transmitting antennae are arranged in a defined position and orientation above the object to be examined.

2. The magnetic resonance system of claim 1, wherein positions of the second transmitting antennae, as viewed in a vertical direction, are independently adjustable.

3. The magnetic resonance system of claim 1, further comprising a cooling circuit for a liquid cooling medium, wherein the cooling circuit is connected to and configured to cool the first transmitting antennae.

4. The magnetic resonance system of claim 1, wherein:
the send structure further comprises third transmitting antennae configured to load the examination volume with the high frequency excitation field (B1);
the third transmitting antennae are inherently stable and are detachably secured to the examination table, to the tunnel wall, or to the examination table and to the tunnel wall; and
during loading of the examination volume with the high frequency excitation field, the third transmitting antennae (B1) are arranged in a defined position and orientation to a side of the object to be examined.

5. The magnetic resonance system of claim 1, wherein the send structure is configured to load substantially all of the examination volume with the excitation field (B1).

6. The magnetic resonance system of claim 1, wherein the send structure is configured to load only a portion of the examination volume with the excitation field (B1), and wherein the portion of the examination volume is arranged to a side relative to a cross-section of the examination volume.

7. The magnetic resonance system of claim 1, further comprising local coils that are arranged radially inside of the send structure, wherein the local coils are configured to receive magnetic resonance signals emitted by the object to be examined.

8. The magnetic resonance system of claim 1, wherein the basic magnetic field (B0) has a strength of at least 3.0 Tesla.

9. The magnetic resonance system of claim 2, further comprising a cooling circuit for a liquid cooling medium, wherein the cooling circuit is connected to and configured to cool the first transmitting antennae.

10. The magnetic resonance system of claim 2, wherein:
the send structure further comprises third transmitting antennae configured to load the examination volume with the high frequency excitation field (B1);
the third transmitting antennae are inherently stable and are detachably secured to the examination table, to the tunnel wall, or to the examination table and to the tunnel wall; and
during loading of the examination volume with the high frequency excitation field, the third transmitting antennae (B1) are arranged in a defined position and orientation to a side of the object to be examined.

11. The magnetic resonance system of claim 3, wherein:
the send structure further comprises third transmitting antennae configured to load the examination volume with the high frequency excitation field (B1);
the third transmitting antennae are inherently stable and are detachably secured to the examination table, to the tunnel wall, or to the examination table and to the tunnel wall; and
during loading of the examination volume with the high frequency excitation field, the third transmitting antennae (B1) are arranged in a defined position and orientation to a side of the object to be examined.

12. The magnetic resonance system of claim 2, wherein the send structure is configured to load substantially all of the examination volume with the excitation field (B1).

13. The magnetic resonance system of claim 3, wherein the send structure is configured to load substantially all of the examination volume with the excitation field (B1).

14. The magnetic resonance system of claim 4, wherein the send structure is configured to load substantially all of the examination volume with the excitation field (B1).

15. The magnetic resonance system of claim 2, wherein the send structure is configured to load only a portion of the examination volume with the excitation field (B1), and wherein the portion of the examination volume is arranged to a side relative to a cross-section of the examination volume.

16. The magnetic resonance system of claim 3, wherein the send structure is configured to load only a portion of the examination volume with the excitation field (B1), and wherein the portion of the examination volume is arranged to a side relative to a cross-section of the examination volume.

17. The magnetic resonance system of claim 4, wherein the send structure is configured to load only a portion of the examination volume with the excitation field (B1), and wherein the portion of the examination volume is arranged to a side relative to a cross-section of the examination volume.

18. The magnetic resonance system of claim 2, further comprising local coils that are arranged radially inside of the send structure, wherein the local coils are configured to receive magnetic resonance signals emitted by the object to be examined.

19. The magnetic resonance system of claim 3, further comprising local coils that are arranged radially inside of the send structure, wherein the local coils are configured to receive magnetic resonance signals emitted by the object to be examined.

20. The magnetic resonance system of claim 4, further comprising local coils that are arranged radially inside of the send structure, wherein the local coils are configured to receive magnetic resonance signals emitted by the object to be examined.
